(19) United States
(12) Patent Application Publication
(10) Pub. No.: US 2025/0160051 A1
(43) Pub. Date: May 15, 2025

(54) SPAD TYPE PHOTODETECTOR

(71) Applicant: COMMISSARIAT A L'ENERGIE ATOMIQUE ET AUX ENERGIES ALTERNATIVES, Paris (FR)

(72) Inventors: Norbert MOUSSY, Grenoble Cedex 09 (FR); François AYEL, Grenoble Cedex 09 (FR); Olivier SAXOD, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 18/928,278

(22) Filed: Oct. 28, 2024

(30) Foreign Application Priority Data
Nov. 10, 2023 (FR) 2312318

(51) Int. Cl. H01L 31/02; H01L 31/107; H01L 31/18

(52) U.S. Cl. CPC H10F 77/959; H10F 30/225; H10F 71/00

(57) ABSTRACT

The invention relates to a photodetector, including a SPAD type photodiode comprising, in a semiconductor substrate, a first doped region of a first conductivity type and a second doped region of a second conductivity type opposite the first conductivity type so as to produce a PN junction; a quenching transistor comprising, in the substrate, a channel of the second conductivity type, a gate electrically isolated from the substrate by a dielectric layer, a third doped region of the first conductivity type flush with an upper face of the substrate. The dielectric layer is inserted between the gate and the first doped region, the channel is delimited by the first doped region and the third doped region.

### TECHNICAL FIELD

The field of the invention is that of photodetectors comprising at least one avalanche photodiode for detecting single photons, also known as a SPAD (“Single Photon Avalanche Diode”) photodiode. The invention also relates to photodetectors comprising a SPAD photodiode array.

### PRIOR ART

A SPAD photodiode is an extremely sensitive detector capable of detecting a single photon. It essentially consists of a PN junction in a semiconductor layer, inversely polarised at a voltage greater than its avalanche threshold, also known as breakdown voltage. This creates an intense electric field inside the SPAD. A photogenerated carrier is then accelerated by the electric field at a sufficient velocity to trigger an impact ionisation phenomenon, or avalanche phenomenon. Thus, a single photon is capable of generating a measurable electrical signal in a very short response time.

Once a signal has been detected, it is necessary to interrupt the avalanche and recharge the SPAD photodiode. For this, a quenching circuit is typically used to control the avalanche phenomenon. The quenching circuit may be passive or active. Active circuits allow better avalanche control but are however bulkier than passive circuits.

The simplest quenching circuit consists of a resistor connected in series with the SPAD photodiode. During the avalanche, the electric current passing through the resistor increases rapidly, intensifying a difference in potential at the resistor terminals by applying Ohm's law, mechanically lowering the difference in potential at the SPAD photodiode terminals. If the resistor is sufficiently resistive, the electric field inside the SPAD photodiode decreases until the avalanche is quenched. The SPAD photodiode then gradually regains its initial polarisation.

The resistor may for example be a 10 μm long weakly doped silicon bar, placed on the edge of the SPAD photodiode. The quenching circuit then occupies a large surface area compared to the size of the SPAD photodiode, this is especially prejudicial in the case of photodetectors comprising a SPAD photodiode array. Furthermore, such a circuit does not allow precise control of the avalanche phenomenon.

To reduce the surface area of the quenching circuit and enhance avalanche control, it is possible to replace the resistor by a transistor. Patent application JP 2022-148028 proposes such a solution. FIG. 8 of this document illustrates a pixel of a photodetector comprising a SPAD photodiode. The SPAD photodiode comprises, in a substrate, a PN junction defining an avalanche zone. The avalanche zone is at a non-zero distance from an upper face of the substrate. The pixel further comprises a PMOS transistor to quench the avalanche and recharge the SPAD photodiode. Doped wells of different types isolate the PMOS transistor from the photodiode cathode. The drain of the PMOS transistor is connected to the photodiode cathode by metallic interconnections (FIGS. 8 and 10). The channel of the PMOS transistor extends along a plane parallel with the upper face of the substrate.

In this embodiment of the prior art, the quenching circuit then occupies a substantial surface area, in particular on account of the presence of the doped wells and the arrangement of the channel of the PMOS transistor. Therefore, there is a need to reduce the surface area of the quenching circuit further.

### DISCLOSURE OF THE INVENTION

The aim of the invention is that of remedying at least in part the drawbacks of the prior art, and more particularly of providing a photodetector comprising a SPAD type photodiode and less bulky quenching circuit than in the prior art.

For this, the subject matter of the invention is a photodetector, including a SPAD type photodiode and a quenching transistor. The SPAD type photodiode comprises, in a semiconductor substrate, a first doped region of a first conductivity type and a second doped region of a second conductivity type opposite the first conductivity type so as to create a PN junction. The quenching transistor comprises, in the substrate, a channel of the second conductivity type, a gate electrically isolated from the substrate by a dielectric layer, and a third doped region of the first conductivity type flush with an upper face of the substrate. The photodetector is such that the dielectric layer is inserted between the gate and the first doped region, and the channel is delimited by the first doped region and the third doped region.

Some preferred yet non-limiting aspects of this photodetector are as follows.

The gate may extend in the substrate from the upper face of the substrate, and the first doped region of the photodiode may be separated from the upper face by a non-zero distance.

The photodiode may further comprise a fourth doped region of the second conductivity type flush with the upper face of the substrate.

The substrate may comprise a first doped layer and a second doped layer, both of the second conductivity type, such that the second doped layer has a different dopant atom concentration from a dopant atom concentration of the first doped layer, the second doped region may extend in the first doped layer and the channel may extend in the second doped layer.

The substrate may further comprise a doped upper layer of the second conductivity type, having a dopant atom concentration strictly less than the dopant atom concentration of the second doped layer, arranged such that the second doped layer may be inserted between the first doped layer and the doped upper layer, and the fourth doped region may extend in the doped upper layer.

The third doped region may comprise a first doped zone and a second doped zone of the first conductivity type, the photodetector being capable of being such that the first doped zone has a dopant atom concentration strictly greater than a dopant atom concentration of the second doped zone, and may be included in the second doped zone.

The dielectric layer may define with the first doped region 201 a plane substantially parallel with the upper face, the first doped region and the gate being capable of extending on either side of this plane.

The PN junction may be of ellipsoid shape.

The gate may fill a recess of the substrate, and the first doped region may surround the recess.

The recess may comprise a shoulder, and the first doped region may mould the shoulder.

The channel may be facing a portion of the dielectric layer between 7 nm and 20 nm in thickness.

The quenching transistor may belong to a quenching circuit configured to apply a fixed polarisation voltage V_{G} to the gate.

The first conductivity type may be an N-type, and the second conductivity type may be a P-type.

The photodetector may further comprise a read circuit electrically connected to the anode of the photodiode

The photodetector may be a back-illuminated photodiode.

The invention also relates to a method for manufacturing this photodetector, optionally including one or more preferential features.

The manufacturing method comprises the following steps: producing a recess in a substrate; covering the recess with a dielectric layer; filling the recess with a doped polycrystalline semiconductor material of the first conductivity type to obtain a gate electrically isolated from the substrate by the dielectric layer.

Producing the recess may comprise a first etching of a first cavity from an upper face of the substrate, the first cavity having a bottom and a lateral wall, covering the bottom and the lateral wall with a protective layer, removing the protective layer on a part of the bottom of the first cavity, while retaining the protective layer on the lateral wall, a second selective etching with respect to the protective layer of a second cavity from the bottom of the first cavity.

The method may further comprise a step of vapour-phase dopant atom diffusion doping between the step of producing the recess and the step of covering the recess with the dielectric layer.

### BRIEF DESCRIPTION OF THE DRAWINGS

Other aspects, aims, advantages and features of the invention will become more apparent upon reading the following detailed description of preferred embodiments thereof, given as a non-limiting example, and made with reference to the appended drawings, wherein:

FIG. 1 is a schematic sectional view of a photodetector according to a first embodiment comprising a planar type SPAD photodiode;

FIG. 2 is a top view of a photodetector according to the first or the second embodiment;

FIG. 3 is a schematic sectional view of a photodetector according to a second embodiment comprising a needle type SPAD photodiode;

FIG. 4 is an electrical diagram of an electronic circuit comprising a SPAD photodiode according to the first or the second embodiment;

FIG. 5 is a dynamic simulation of the triggering and stoppage of an avalanche phenomenon in a photodetector according to the second embodiment.

### DETAILED DISCLOSURE OF PARTICULAR EMBODIMENTS

In the figures and in the remainder of the description, the same references represent identical or similar elements. In addition, the various elements are not shown to scale so as to promote clarity of the figures. Moreover, the different embodiments and variants are not mutually exclusive and can be combined together. Unless indicated otherwise, the terms “substantially”, “about”, “of the order of” mean within a 10% margin, and preferably within a 5% margin. Moreover, the terms “included between . . . and . . . ” and the like mean that the bounds are included, unless stated otherwise.

“Based on” means that the material is a compound formed from at least the same elements of the semiconductor compound of interest.

Throughout the description, when dopant atom concentrations of two regions or two zones are compared, the mean concentrations within these regions are compared. Thus, when it is said that a zone A has a dopant atom concentration greater than a dopant atom concentration of a zone B, it means that the means dopant atom concentration within the volume of zone A is greater than the mean dopant atom concentration within the volume of zone B.

The invention relates to a photodetector, and to a method for manufacturing such a photodetector. The photodetector includes a SPAD type photodiode and a quenching transistor to quench an avalanche phenomenon in the SPAD photodiode. The transistor is NMOS or PMOS type. A common doped region of a semiconductor substrate forms both a cathode (respectively an anode) of the SPAD photodiode and a source (respectively a drain) of the NMOS (respectively PMOS) transistor. Thus, the surface area occupied by the SPAD photodiode and transistor assembly is reduced.

The common doped region of the substrate may be buried, i.e. it is located at a non-zero distance from an upper face of the substrate. In this case, a doped region flush with the upper face of the substrate defines with the common doped region, a transistor channel which extends along a substantially perpendicular axis to the upper face. Such a transistor is called a vertical channel transistor. This arrangement makes it possible to reduce the surface area occupied by the assembly consisting of the SPAD photodiode and the transistor further.

The invention is particularly advantageous for a photodetector comprising a pixel array extending in a detection plane, because it makes it possible to reduce the size of the pixels.

Particular embodiments will be described with reference to a photodetector including a SPAD type photodiode and a vertical channel transistor having a doped region of a substrate in common. However, these embodiments may be adapted to include any type of avalanche photodiodes, for example avalanche photodiodes having separated charging and/or acceleration and/or multiplication zones.

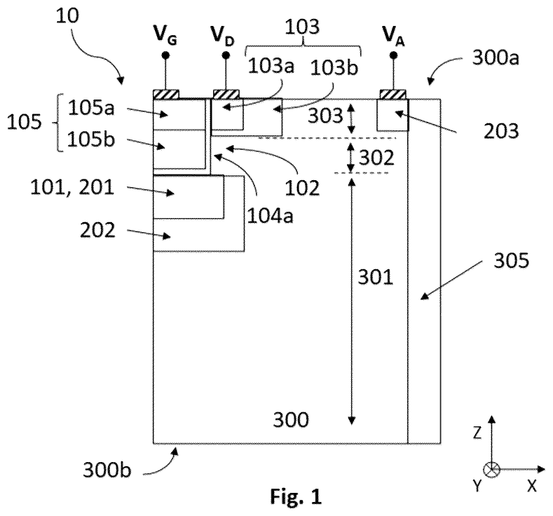

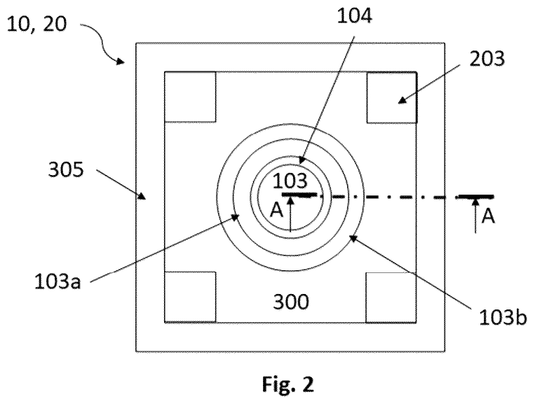

FIG. 1 schematically illustrates a photodetector 10 according to a first embodiment. The photodetector 10 comprises a pixel array extending in a detection plane. For clarity purposes and so as not to overload the figure, half of a pixel has been represented in FIG. 1, viewed along cross-section AA of FIG. 2. FIG. 2 schematically shows a top view of the same pixel, in its entirety.

The photodetector 10 comprises, in a substrate 300, a photodiode 200, a quenching transistor 100 and an isolation trench 305.

The substrate 300 comprises an upper face 300a and a lower face 300b, substantially planar and parallel with the detection plane. The substrate 300 is based on a semiconductor material, here P-doped. The photodetector 10 comprises a stack of insulating and conductive layers (not shown), referred to as interconnection stack, wherein lines of metal and contacts electrically connected to the photodiode 200 and to the quenching transistor 100 may be formed. When the interconnection stack is disposed on the side of the illumination face of the substrate, the photodetector 10 is referred to as a front side illumination (FSI) photodetector. When the interconnection stack is disposed on the side opposite the illumination face of the substrate, the photodetector 10 is referred to as a back side illumination (BSI) photodetector. The photodetector 10 of the first embodiment may be a BSI photodetector with an interconnection stack disposed on the side of the upper face 300a.

Here and hereinafter in the description, an orthogonal three-dimensional direct marker (X, Y, Z) is defined, where the axes X and Y form a plane parallel with the upper face 300a of the substrate 300, the axis X being oriented here parallel with an axis of the pixel array, and where the axis Z is oriented substantially orthogonal to the upper face 300a of the substrate 300, and is oriented from the lower face 300b to the upper face 300a. Hereinafter in the description, the terms “vertical” and “vertically” are understood as relating to an orientation substantially parallel to the Z axis, and the terms “horizontal” and “horizontally” as relating to an orientation substantially parallel with the plane (X, Y). Moreover, the terms “lower” and “upper” are understood as relating to an increasing positioning when moving away from the substrate 300 in the +Z direction.

The photodiode 200 comprises a first doped region 201 of a first conductivity type and a second doped region 202 of a second conductivity type opposite the first conductivity type so as to create a PN junction. The second doped region 202 surrounds the first doped region 201 in a half-space delimited by a plane substantially parallel with the upper face 300a. In this example, the first doped region 201 is N-type and thus form a cathode of the photodiode 200. The second doped region 202 is therefore P-type.

Preferably, the first doped region 201 and the second doped region 202 are each of ellipsoid shape, or hemispherical in the half-space, like the PN junction. This makes it possible to maximise the volume of the region of the substrate 300 inside which a photon is capable of triggering an avalanche, while miniaturising the photodiode 200. This also makes it possible to limit untimely avalanches.

The photodiode 200 further comprises a fourth doped region 203 of the second conductivity type flush with the upper face 300a of the substrate 300. The fourth doped region 203 occupies a peripheral region of the pixel. It is here P-doped and defines an anode of the photodiode 200.

The quenching transistor 100 comprises, in the substrate, a channel 102 inserted between the first doped region 201 and a third doped region 103 of the first conductivity type flush with the upper face 300a of the substrate 300. The channel 102 is of the same conductivity type as that of the substrate 300, hence p-doped in this example. With the types of doping chosen here, the third doped region 103 defines a drain of the transistor and the first doped region 201, a source of the transistor.

The third doped region 103 may have, as shown here, an annular shape. It advantageously comprises a first doped zone 103a which has a dopant atom concentration strictly greater than a dopant atom concentration of a second doped zone 103b. The first doped zone 103a is included in the second doped zone 103b, i.e. the second doped region 103b surrounds the first doped zone 103a in a plane parallel with the upper face 300a. The second doped zone 103b is inserted between the first doped zone 103a and the fourth doped region 203, thus the electric field is reduced in the vicinity of the upper face 300a and an untimely avalanche in this zone may be avoided.

The quenching transistor 100 further comprises a gate 105 electrically isolated from the substrate by a dielectric layer 104. The gate 105 is flush with the upper face 300a of the substrate 300 and has, in this example, a substantially cylindrical shape, of axis parallel with the Z axis. The dielectric layer 104 defines with the first doped region 201 a separating plane substantially parallel with the upper face 300a of the substrate 300, i.e. there is an interface between the dielectric layer 104 and the substantially planar first doped region 201 which is included in this plane. The first doped region 201 and the gate 105 extend mostly on either side of the separating plane. Furthermore, along a direction of the separating plane, the first doped region 201 has a dimension strictly greater than a dimension of the dielectric layer 104. The separating plane is for example identical to the plane delimiting the half-space.

The dielectric layer 104 has a portion 104a facing the channel 102, hereinafter referred to as gate oxide 104a. The gate 105 may be metallic or based on a semiconductor material. In the latter case, it is doped with the first conductivity type or the second conductivity type, here the gate 105 is of the first conductivity type. It may comprise a first doped zone 105a which is flush with the upper face 300a of the substrate 300. The part not included in the first doped zone 105a forms a second doped zone 105b of the gate 105. The first and second doped zones 105a, 105b are of the same conductivity type which may be the first or the second conductivity type, here N-type. The gate oxide 104a and of the channel 102 is facing the second doped zone 105b. Furthermore, the dopant atom concentration of the first doped zone 105a may be strictly greater than the dopant atom concentration of the second doped zone 105b.

The third doped region 103, the gate 105, the first doped region 201 and the second doped region 202 occupy a central region of the pixel. Metallic contacts are disposed in contact with the gate 105, the third doped region 103 and the fourth doped region 203, optionally through a passivation layer not shown. The dopant atom concentrations of the first doped zone 103a of the drain 103, the first doped zone 105a of the gate 105 and of the anode 203 are chosen to lower the contact resistance.

Advantageously, the substrate 300 comprises a first doped layer 301 in contact with a second doped layer 302, both of the second conductivity type. The second doped region 202 extends in the first doped layer 301 and the channel 102 extends in the second doped layer 302. A dopant atom concentration of the second doped layer 302 may be different from, for example strictly less than, a dopant atom concentration of the first doped layer 301. It is thus possible to optimise the resistivity of the channel 102 and the electric field in the photodiode 200 independently of one another. Even more advantageously, the dopant atom concentration of the first doped layer 301 varies gradually along the Z axis so as to attract the photogenerated charges towards the second doped region 202.

Also advantageously, the substrate 300 comprises a doped upper layer 303 of the second conductivity type wherein the third doped region 103, the first and second doped zones 103a, 103b when they are present, and fourth doped region 203 extend. The upper layer 303 is weakly doped. It has for example a dopant atom concentration strictly less than the dopant atom concentration of the second doped layer 302. This makes it possible to decrease the electric field in the vicinity of the upper face 300a and thus avoid any untimely avalanche capable of arising in this zone.

In this example, the first and second doped layers 301, 302 are made of P-doped silicon. The dopant atom concentration of the layer 301 is between 1015 and 1018 atoms/cm³, for example equal to 9.1016 atoms/cm³. That of the second doped layer 302 is between 1015 and 1018, for example equal to 4.1016 atoms/cm³. That of the doped upper layer 303 is between 1014 and 1017, for example equal to 1015 atoms/cm³.

The first doped layer 301 has for example a thickness between 1 μm and 15 μm. The second doped layer 302 has a thickness between 500 nm and 5 μm, preferably between 1 and 4 μm. The doped upper layer 303 has a thickness between 100 nm and 500 nm.

The fourth doped region 203 has a dopant atom concentration between 1017 and 5.1020 atoms/cm³. That of the first doped region 201 is between 1017 and 5.1020 atoms/cm³. That of the second doped region 202 is between 1016 and 1020 atoms/cm³. That of the first doped zone 103a is between 1017 and 5.1020 atoms/cm³. That of 103b is between 1016 and 1019 atoms/cm³.

The first and second doped zones 105a, 105b are here made of polycrystalline silicon. The second doped zone 105b has a dopant atom concentration between 1017 and 5.1020. That of the first doped zone 105a is between 1017 and 5.1020 atoms/cm³.

The gate 105 has a cross-section perpendicular to the Z axis of between 100 nm and 1 μm in diameter, for example equal to 600 nm. The gate oxide 104a has a thickness measured in a direction parallel with the upper face 300a of the substrate 300 between 2 nm and 100 nm, preferably between 2 and 20 nm, for example equal to 7 nm. The length of the channel 102 measured in a direction parallel with the Z axis is between 500 nm and 5 μm, preferably between 1 μm and 4 μm, for example equal to 1 μm.

The first and second doped layers 301, 302 and the doped upper layer 303 are for example in-situ doped epitaxial layers.

The pixels are separated laterally from each other isolation trenches or walls 305 extending vertically through the substrate 300, for example along the entire thickness of the first doped layer 301. The isolation trenches 305 are for example capacitive isolation trenches, for example CDTI (Capacitive Deep Trench Isolation) type, each comprising a core or central wall made of an electrically conductive material, for example doped polycrystalline silicon, and a lateral coating made of an electrically insulating material, for example silicon oxide. Alternatively, the isolation trenches 305 are isolating trenches entirely filled with a dielectric material, for example silicon oxide, for example DTI (Deep Trench Isolation) type trenches. The isolation trenches 305 are for example formed from the upper face 300a of the substrate 300.

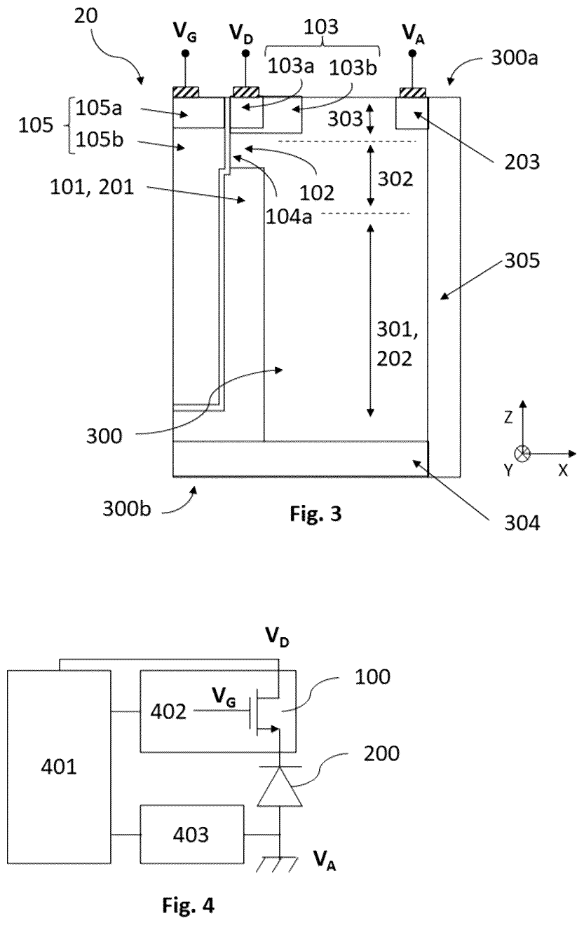

FIG. 3 schematically illustrates a photodetector 20 according to a second embodiment. For the same reasons disclosed in relation to FIG. 1, half of a pixel has been represented in FIG. 3, viewed along cross-section AA of FIG. 2. FIG. 2 is also a schematic top view of a pixel of the second embodiment, considered as a whole. Only differences with respect to the first embodiment will be described here. The photodetector 20 of the second embodiment may be a BSI detector with an interconnection stack disposed on the upper face 300a of the substrate 300.

The substrate 300 accommodates a non-through recess. The first doped region 201 surrounds this recess on a lower part, i.e. the recess has a bottom and a lateral wall, and the first doped region 201 covers the bottom and a lower part of the lateral wall. The recess extends in depth in the substrate 300, typically along a depth of several micrometres, for example between 5 and 25 μm. It is coated with the dielectric layer 104 and filled with the gate 105. The gate 105 therefore extends from the upper face 300a of the substrate 300 to the bottom of the recess.

When the gate 105 is based on a semiconductor material, it may comprise a first doped zone 105a of the first conductivity type or the second conductivity type, here the first conductivity type, which is flush with the upper face 300a of the substrate 300. The part not included in the first doped zone 105a may comprise one or more different doped zones of the first conductivity type. For example, the gate oxide 104a may be facing a second doped zone 105b. The first doped region 201 may be facing the second doped zone 105b and/or a third doped zone 105c not shown. The dopant atom concentrations of doped zones 105a, 105b, 105c may be different, for example the dopant atom concentration of the first doped zone 105a may be strictly greater than the dopant atom concentration of the second doped zone 105b when it is present. The third doped zone 105c may be a dielectric.

The recess may comprise a shoulder, i.e. in the vicinity of a plane parallel with the upper face 300a, the area of a cross-section of the recess parallel with the upper face 300a increases rapidly in the direction +Z. In this case, the area of a cross-section of the first doped region 201 in this plane is strictly greater than the maximum area of the cross-section of the recess parallel with the upper face 300a in the vicinity of this plane. Preferably, the first doped region 201 moulds the shoulder.

The first doped region 201 and the second doped region 202 may rest, as shown here, on a doped lower layer 304 of the first conductivity type or the second conductivity type. The doped lower layer 304 has a dopant atom concentration less than the first doped region 201 and the second doped region 202. The second doped region 202 extends laterally from the first doped region 201 to the isolation trench 305.

FIG. 4 is an electrical diagram of an electronic circuit comprising a photodiode 200 according to the first or the second embodiment, in the case where the first conductivity type is an N-type, and the second conductivity type is a P-type.

The electronic circuit further comprises a supply circuit 401, a quenching circuit 402 and a read circuit 403.

The quenching circuit 402 comprises a quenching transistor 100 according to the first or the second embodiment. It is configured to apply a potential V_{G} to the gate 105 of the quenching transistor 100. The potential V_{G} is here a fixed potential. Alternatively, the potential V_{G} may be variable, for example slaved to a drain current i_{D} of the quenching transistor 100. In this case, the quenching circuit 402 is capable of applying a first potential V_{G} for which the channel of the quenching transistor 100 is open during the avalanche and a second potential V_{G} for which the channel of the quenching transistor 100 is closed once the avalanche stops, for a time of a few nanoseconds.

The supply circuit 401 is configured to apply a fixed potential V_{D} to the drain of the quenching transistor 100. The source of the quenching transistor 100 is, for its part, electrically connected to the cathode of the photodiode 200, which is consistent with the explanations given in relation to the first and second embodiments. The anode of the photodiode 200 is electrically connected to a potential source V_{A}.

The read circuit 403 is electrically connected to the anode of the photodiode 200. It is intended to measure and/or detect a signal emitted by the photodiode 200 following the triggering of an avalanche phenomenon. It may comprise, for example, a capacitor connected in series with a resistor, or an inverter.

For example, the anode of the photodiode 200 is electrically connected to the ground; the potential V_{A} is then equal to 0 V. The potential V_{G} is fixed and is between 18.0 and 18.2 V, for example equal to 18.2 V. The potential V_{D} is greater than the breakdown voltage of the photodiode 200, for example greater than the breakdown voltage of 2V, for example equal to 18.6 V.

Alternatively, the gate 105 of the quenching transistor 100 may be connected to the ground, such that V_{G} is equal to 0 V. The potential V_{D} is equal to −0.4 V and the potential V_{A} is equal to −18.6 V.

In the absence of photons, the quenching transistor 100 is locked. The cathode of the photodiode 200 and the source of the quenching transistor 100, which correspond to the first doped region 201, are at a potential Vs close to V_{D}. The gate 105 is at a potential V_{G} close to Vs, for example V_{G} differs from Vs by a voltage close to the threshold voltage of the quenching transistor 100, thus the electrical resistance of the channel 102 has a high value Rᵢ. A difference in potential Vs-V_{A} then creates an intense internal electric field inside the photodiode 200. When an incident photon generates an electron-hole pair in an absorption region of the photodiode 200, the electron is accelerated by the internal electric field until a sufficient velocity to trigger an avalanche phenomenon is reached. The electron thus generates numerous other electrons which are collected by the first doped region 201, generating a drain current i_{D}. The resistance of the channel 102 Rᵢ being high, the potential Vs decreases rapidly. The difference in potential Vs-V_{A} then decreases; it falls below the breakdown voltage and the avalanche stops. The drop in Vs then causes a decrease in the electrical resistance of the channel 102 until it reaches a low value Ra for recharging the photodiode 200, such that the potential Vs and the electrical resistance of the channel 102 progressively increase to regain their initial values, before the triggering of the avalanche.

Using simulation tools known to a person skilled in the art, such as for example the TCAD Sentaurus simulator by Synopsys, it is possible to adjust the settings of the quenching transistor 100 to set the high and low values Rᵢ, Ra of the electrical resistance of the channel 102, and thus control the avalanche in the photodiode 200. For example, it is possible to adjust: the thickness of the gate oxide 104a, the length of the channel 102, the dopant atom concentrations of the channel 102 and the gate 105.

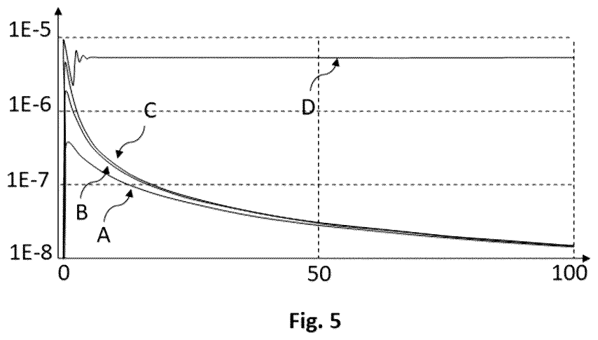

FIG. 5 is a dynamic simulation of the triggering and stoppage of an avalanche phenomenon in a photodetector according to the second embodiment. Here, the settings of the NMOS type quenching transistor 100 are selected so as to quench an avalanche in the photodiode 200. In particular, the thickness of the gate oxide 104a is equal to 7 nm, the length of the channel 102 is equal to 1 μm, the dopant atom concentration of the channel 102 is equal to 4.1016 atoms/cm³ and the dopant atom concentration of the gate 105 is equal to 2.1020 atoms/cm³.

Here, the variation of the drain current i_{D} in amperes as a function of time in ns (nanoseconds) is shown. The scale used is semi-logarithmic on the ordinate axis. Curve A is obtained for a gate potential V_{G} equal to 18.0 V, curve B for a potential V_{G} equal to 18.1 V, curve C for a potential V_{G} equal to 18.2 V and curve D for a potential V_{G} equal to 18.3 V. Curves A, B and C show a quenching of the avalanche and recharging of the photodiode 200. On curve D, the drain current i_{D} has a series of peaks before settling at a high threshold for example the avalanche is maintained, including the channel 102 of the quenching transistor 100.

A manufacturing method potentially suitable for producing a photodetector according to the first embodiment is now described.

During a first step, a planar photodiode 200 is produced in a first doped epitaxial layer 301, using conventional method steps of the semiconductor industry, such that a first doped region 201 is flush with an upper face of the first doped layer 301. An example of such a sequence of method steps is disclosed in patent application FR3121282 A1, with reference to FIGS. 3 to 9. The first doped layer 301 is based on P-doped silicon during the epitaxial growth.

During a second step, a second doped layer 302 is grown epitaxially on the upper face of the first doped layer 301. The second doped layer 302 is based on P-doped silicon during the epitaxial growth.

During a third step, a doped upper layer 303 is grown epitaxially on a face opposite the first doped layer 301 of the second doped layer 302, to produce a stack of a substrate 300. The stack comprises the first and second doped layers 301, 302 and the doped upper layer 303. The substrate 300 has an upper face 300a belonging to the doped upper layer 303. The doped upper layer 303 is based on P-doped silicon during the epitaxial growth.

During a fourth step, a recess, for example cylindrical, is etched from the upper face 300a of the substrate 300, so as to pass through the doped upper layer 303 and the second doped layer 302. The recess has a bottom substantially parallel with the upper face 300a, and a lateral wall substantially perpendicular to the bottom. The bottom is in contact with the first doped region 201 and entirely included therein.

During a fifth step, a dielectric layer 104 is deposited in a conforming manner in the recess to cover the bottom and the lateral wall of the recess, for example by CVD or LPCVD. Alternatively, thermal oxidation may be used. On the lateral wall of the recess, the dielectric layer 104 has a thickness between 2 nm and 100 nm, preferably between 2 nm and 20 nm, for example equal to 7 nm.

During a sixth step, the recess is filled with N-type doped polycrystalline silicon to produce a gate 105 of a quenching transistor 100 wherein the source comprises the first doped region 201.

During a seventh step, isolation trenches 305 are produced through the doped upper layer 303, the second doped layer 302 and the first doped layer 301.

A seventh step comprises dopant atom implantations to produce a first doped zone 105a of the gate 105, a first doped zone 103a and a second doped zone 103b to produce a drain of the quenching transistor 100, a fourth doped region 203 to produce an anode of the photodiode 200, all flush with the upper face 300a.

A manufacturing method potentially suitable for producing a photodetector according to the second embodiment is now described.

During a first step, a stack of three silicon layers is grown epitaxially. The stack comprises in the following order a first doped layer 301 P, a second doped layer 302 P having a dopant atom concentration strictly less than a dopant atom concentration of the first doped layer 301 and a doped upper layer 303 having a dopant atom concentration strictly less than a dopant atom concentration of the second doped layer 302. The three layers are based on silicon.

During a second step, a first cavity, for example cylindrical, is etched from an upper face 300a of the stack, so as to pass through the doped upper layer 303 and at least a part of the second doped layer 302. The first cavity has a bottom substantially parallel with the upper face 300a, and a lateral wall substantially perpendicular to the bottom.

During a third step, a protective layer is deposited in a conforming manner in the first cavity to cover the bottom and the lateral wall of the first cavity, for example by CVD or LPCVD. Alternatively, thermal oxidation may be used. The protective layer has a thickness between 5 nm and 50 nm.

During a fourth step, a through opening is etched in the protective layer to reach the bottom of the first cavity, while retaining a non-zero thickness of the protective layer on the lateral wall of the first cavity.

A fifth step comprises a directional etching of the first doped layer 301 selectively with respect to the protective layer, in order to obtain a second cavity in the first doped layer 301. The second cavity extends in depth in a part of the first doped layer 301, typically along a depth of several micrometres, for example between 5 and 25 μm. It has a bottom substantially parallel with the upper face 300a, and a lateral wall substantially perpendicular to the bottom. The first and the second cavities form a recess of a substrate 300 which comprises the stack.

A sixth step comprises vapour diffusion doping with dopant atoms, for example phosphorus or arsenic, to obtain an N-type first doped region 201 surrounding the second cavity, and preferably a lower part of the first cavity. The first doped region 201 is intended to be a cathode of a photodiode 200.

During a seventh step, a dielectric coating is deposited in a conforming manner in the first cavity and the second cavity to cover the bottoms and walls of the first and second cavities, for example by CVD or LPCVD. Alternatively, thermal oxidation may be used to obtain the dielectric coating. This step may be preceded by a removal of the protective layer. Following this step, the recess is coated with a dielectric layer 104 which comprises the protective layer and the dielectric coating if the protective layer is dielectric and has not been removed. Otherwise, the dielectric layer 104 is the dielectric coating. Following this step, the dielectric layer 104 has a portion 104a facing the second doped layer 302 which has a thickness between 2 nm and 100 nm, preferably between 2 nm and 20 nm, for example equal to 7 nm.

During an eighth step, the recess is filled with N-type doped polycrystalline silicon to produce a gate 105 of a quenching transistor 100 wherein the source comprises the first doped region 201.

During a ninth step, isolation trenches 305 are produced through the doped upper layer 303, the first doped layer 301 and the second doped layer 302.

A tenth step comprises dopant atom implantations to produce a first doped zone 105a of the gate 105, a first doped zone 103a and a second doped zone 103b to produce a drain of the quenching transistor 100, a fourth doped region 203 to produce an anode of the photodiode 200, all flush with the upper face 300a.

Particular embodiments have just been described. Various variants and modifications will become apparent to a person skilled in the art. It is particularly possible to invert all doping types. For an N-type doping in silicon, it is for example possible to use phosphorus, arsenic, antimony, or bismuth. For a P-type doping in silicon, it is for example possible to use boron, aluminium, gallium or bismuth.

1. Photodetector, including:
a semiconductor substrate comprising an upper face,
a SPAD type photodiode comprising, in the substrate, a first doped region of a first conductivity type and a second doped region of a second conductivity type opposite the first conductivity type so as to create a PN junction;
a quenching transistor comprising, in the substrate,
a channel of the second conductivity type,
a gate electrically isolated from the substrate by a dielectric layer,
a third doped region of the second conductivity type flush with the upper face of the substrate;
wherein
the dielectric layer is inserted between the gate and the first doped region,
the channel is delimited by the first doped region and the third doped region.

2. Photodetector according to claim 1, wherein the gate extends in the substrate from the upper face of the substrate, and the first doped region of the photodiode is separated from the upper face by a non-zero distance.

3. Photodetector according to claim 2, wherein the photodiode further comprises a fourth doped region of the second conductivity type flush with the upper face of the substrate.

4. Photodetector according to claim 2, wherein the substrate comprises a first doped layer and a second doped layer, both of the second conductivity type, such that the second doped layer has a different dopant atom concentration from a dopant atom concentration of the first doped layer, the second doped region extends in the first doped layer and the channel extends in the second doped layer.

5. Photodetector according to claim 4, wherein the photodiode further comprises a fourth doped region of the second conductivity type flush with the upper face of the substrate, wherein the substrate further comprises a doped upper layer of the second conductivity type, having a dopant atom concentration strictly less than the dopant atom concentration of the second doped layer, arranged such that the second doped layer is inserted between the first doped layer and the doped upper layer, and wherein the fourth doped region extends in the doped upper layer.

6. Photodetector according to claim 5, wherein the third doped region comprises a first doped zone and a second doped zone of the first conductivity type, the photodetector being such that the first doped zone has a dopant atom concentration strictly greater than a dopant atom concentration of the second doped zone, and is included in the second doped zone.

7. Photodetector according to claim 2, wherein the dielectric layer defines with the first doped region a plane substantially parallel with the upper face, the first doped region and the gate extending on either side of this plane.

8. Photodetector according to claim 7, wherein the PN junction is of ellipsoid shape.

9. Photodetector according to claim 2, wherein the gate fills a recess of the substrate, and the first doped region surrounds the recess.

10. Photodetector according to claim 9, wherein the recess comprises a shoulder and the first doped region conforms to the shoulder.

11. Photodetector according to claim 1, wherein the channel is facing a portion of the dielectric layer between 7 nm and 20 nm in thickness.

12. Photodetector according to claim 1 wherein the quenching transistor belongs to a quenching circuit configured to apply a fixed polarisation voltage V_{G} to the gate.

13. Photodetector according to claim 1, wherein the first conductivity type is an N-type and the second conductivity type is a P-type.

14. Photodetector according to claim 13 further comprising a read circuit electrically connected to the anode of the photodiode

15. Photodetector according to claim 1, wherein the photodetector is a back side illumination photodetector.

16. Method for manufacturing a photodetector according to claim 1, comprising the following steps:
producing a recess in a substrate,
covering the recess with a dielectric layer,
filling the recess with a doped polycrystalline material of the first conductivity type to obtain a gate electrically isolated from the substrate by the dielectric layer.

17. Manufacturing method according to claim 16 wherein producing the recess comprises
a first etching of a first cavity from an upper face of the substrate, the first cavity having a bottom and a lateral wall,
a covering of the bottom and the lateral wall with a protective layer,
a removal of the protective layer on a part of the bottom of the first cavity, while retaining the protective layer on the lateral wall,
a second selective etching with respect to the protective layer of a second cavity from the bottom of the first cavity,
the method also comprising:
a step of vapour-phase dopant atom diffusion doping between the step of producing the recess and the step of covering the recess with the dielectric layer.
